(19) United States
(12) Patent Application Publication
(10) Pub. No.: US 2025/0393385 A1
(43) Pub. Date: Dec. 25, 2025

(54) PHOTOELECTRIC CONVERSION ELEMENT AND IMAGING DEVICE

(71) Applicant: Panasonic Intellectual Property Management Co., Ltd., Osaka (JP)

(72) Inventors: MASAYA HIRADE, Osaka (JP); MASUMI IZUCHI, Osaka (JP)

(21) Appl. No.: 19/307,089

(22) Filed: Aug. 22, 2025

Related U.S. Application Data
(63) Continuation of application No. PCT/JP2024/004921, filed on Feb. 14, 2024.

(30) Foreign Application Priority Data
Mar. 14, 2023 (JP) 2023-039375

(51) Int. Cl. H10K 30/86; H10K 30/20; H10K 39/32

(52) U.S. Cl. CPC H10K 30/86; H10K 30/20; H10K 39/32

(57) ABSTRACT

A photoelectric conversion element includes a photoelectric conversion layer that contains donor and acceptor semiconductor materials and converts light into a signal charge, a first electrode that collects the signal charge, a second electrode opposed to the first electrode with the photoelectric conversion layer disposed therebetween, and a charge injection layer between the second electrode and the photoelectric conversion layer. The charge injection layer includes a first layer and a second layer located on the first layer. The first layer has an ionization potential that is larger than that of the second layer. The first layer has an electron affinity that is larger than that of the second layer. A difference between the electron affinity of the first layer and the ionization potential of the second layer is smaller than a difference between the electron affinity of the acceptor semiconductor material and the ionization potential of the donor semiconductor material.

### BACKGROUND

### 1. Technical Field

The present disclosure relates to a photoelectric conversion element and an imaging device.

### 2. Description of the Related Art

A photoelectric conversion element using a thin film of a semiconductor material takes out charge generated by light as an electrical signal and thus can be used as an optical sensor or the like. A photoelectric conversion element disclosed in Japanese Patent No. 5969843 includes an electron blocking layer or a hole blocking layer between a thin film of a photoelectric conversion material and an electrode to prevent backflow of charge from the electrode. Furthermore, Japanese Unexamined Patent Application Publication No. 2018-092990 discloses a method of changing bias voltages applied to electrodes connected to two ends of the photoelectric conversion element.

### SUMMARY

In one general aspect, the techniques disclosed here feature a photoelectric conversion element comprising: a photoelectric conversion layer that contains a donor semiconductor material and an acceptor semiconductor material and that converts light into a signal charge; a first electrode that collects the signal charge; a second electrode opposed to the first electrode with the photoelectric conversion layer disposed between the first electrode and the second electrode; and a charge injection layer located between the second electrode and the photoelectric conversion layer. The charge injection layer includes a first layer and a second layer located on the first layer. The first layer has an ionization potential that is larger than an ionization potential of the second layer. The first layer has an electron affinity that is larger than an electron affinity of the second layer. A difference between the electron affinity of the first layer and the ionization potential of the second layer is smaller than a difference between the electron affinity of the acceptor semiconductor material and the ionization potential of the donor semiconductor material.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic cross-sectional view illustrating a configuration of a photoelectric conversion element according to an embodiment;

FIG. 2 is an exemplary energy band diagram of the photoelectric conversion element according to the embodiment;

FIG. 3 is an exemplary energy band diagram of the photoelectric conversion element according to the embodiment when a reverse bias voltage is applied;

FIG. 4 is an exemplary energy band diagram of the photoelectric conversion element according to the embodiment when a forward bias voltage is applied;

FIG. 5 is a schematic cross-sectional view illustrating a configuration of another photoelectric conversion element according to the embodiment;

FIG. 6 is an exemplary energy band diagram of the other photoelectric conversion element according to the embodiment;

FIG. 7 illustrates an example of circuitry of an imaging device according to the embodiment;

FIG. 8 is a schematic cross-sectional view illustrating a device structure of pixels in the imaging device according to the embodiment;

FIG. 9 schematically illustrates a portion of circuitry of a pixel according to the embodiment;

FIG. 10 is a timing chart indicating a voltage supplied to an upper electrode of a photoelectric converter according to the embodiment and an example of timing of operation in each row of a pixel array of the imaging device;

FIG. 11 is a timing chart indicating an example of an operation of adjusting sensitivity of photoelectric conversion by using a pulse duty control method in the imaging device according to the embodiment;

FIG. 12 indicates current density-voltage characteristics when a bias voltage is applied to the photoelectric conversion element of Example; and

FIG. 13 indicates current density-voltage characteristics when a bias voltage is applied to the photoelectric conversion element of Comparative Example.

### DETAILED DESCRIPTIONS

When a photoelectric conversion element is used in a device such as an imaging device, a reduction in parasitic sensitivity, which is unintentional parasitic sensitivity, is desired to improve the S/N (signal noise) ratio of the imaging device or the like.

One non-limiting and exemplary embodiment provides a photoelectric conversion element and the like in which parasitic sensitivity can be reduced.

### Overview of Present Disclosure

As an overview of an aspect of the present disclosure, an example of a photoelectric conversion element and an imaging device according to the present disclosure will be described below.

A photoelectric conversion element according to a first aspect of the present disclosure includes: a photoelectric conversion element that contains a donor semiconductor material and an acceptor semiconductor material and that converts light into a signal charge; a first electrode that collects the signal charge; a second electrode opposed to the first electrode with the photoelectric conversion layer disposed between the first electrode and the second electrode; and a charge injection layer located between the second electrode and the photoelectric conversion layer. The charge injection layer includes a first layer and a second layer located on the first layer. The first layer has an ionization potential that is larger than an ionization potential of the second layer. The first layer has an electron affinity that is larger than an electron affinity of the second layer. A difference between the electron affinity of the first layer and the ionization potential of the second layer is smaller than a difference between the electron affinity of the acceptor semiconductor material and the ionization potential of the donor semiconductor material.

In the charge injection layer including the first and second layers having the above ionization potentials and electron affinities, charges are likely to be generated at the interface between the first layer and the second layer. Thus, when the signal charge collected at the first electrode is read out after the migration of the signal charge to the first electrode is stopped, the signal charge remains in the photoelectric conversion layer too. However, of the charges generated in the charge injection layer, the charge of opposite polarity to the signal charge moves toward the first electrode and can recombine with the remaining signal charge in the photoelectric conversion layer. This reduces transfer of the signal charge to the first electrode during the signal charge readout regardless of the amount of light applied to the photoelectric conversion layer, reducing generation of unintended sensitivity. Thus, according to this aspect, parasitic sensitivity can be reduced.

In a second aspect of the present disclosure, which is the photoelectric conversion element according to the first aspect, the signal charge may be a hole.

The above-described configuration enables, when the hole is read out as the signal charge, the hole remaining in the photoelectric conversion layer to recombine with the electron generated in the charge injection layer, and thus parasitic sensitivity can be reduced.

In a third aspect of the present disclosure, which is the photoelectric conversion element according to the second aspect, the first layer may be located between the second layer and the photoelectric conversion layer.

The above-described configuration can reduce an energy barrier for migration of electrons generated in the charge injection layer to the photoelectric conversion layer.

In a fourth aspect of the present disclosure, which is the photoelectric conversion element according to the second aspect or the third aspect, the photoelectric conversion element may further include an electron blocking layer located between the first electrode and the photoelectric conversion layer.

The above-described configuration can reduce dark current.

In a fifth aspect of the present disclosure, which is the photoelectric conversion element according to the first aspect, the signal charge may be an electron.

The above-described configuration enables, when the electron is read out as the signal charge, the electron remaining in the photoelectric conversion layer to recombine with the hole generated in the charge injection layer, and thus parasitic sensitivity can be reduced.

In a sixth aspect of the present disclosure, which is the photoelectric conversion element according to the fifth aspect, the second layer may be located between the first layer and the photoelectric conversion layer.

The above-described configuration can reduce the energy barrier for migration of holes generated in the charge injection layer to the photoelectric conversion layer.

In a seventh aspect of the present disclosure, which is the photoelectric conversion element according to the fifth aspect or the sixth aspect, the photoelectric conversion element may further include a hole blocking layer located between the first electrode and the photoelectric conversion layer.

The above-described configuration can reduce dark current.

In an eighth aspect of the present disclosure, which is the photoelectric conversion element according to any one of the first to seventh aspects, the first layer may contain a material identical to the acceptor semiconductor material.

The above-described configuration enables production of a photoelectric conversion element in which parasitic sensitivity can be reduced with fewer kinds of materials.

In a ninth aspect of the present disclosure, which is the photoelectric conversion element according to any one of the first to eighth aspects, the second layer may contain a material identical to the donor semiconductor material.

The above-described configuration enables production of a photoelectric conversion element in which parasitic sensitivity can be reduced with fewer kinds of materials.

In a tenth aspect of the present disclosure, which is the photoelectric conversion element according to the ninth aspect, the photoelectric conversion layer may be a mixed film containing the donor semiconductor material and the acceptor semiconductor material, and the first layer may contain a material identical to the acceptor semiconductor material.

In the above-described configuration, the donor and acceptor semiconductor materials of a mixed film are less affected by stabilization than those of single-material films, and the difference between the electron affinity and the ionization potential increases. Thus, even when the charge injection layer and the photoelectric conversion layer contain the same material, the difference between the electron affinity of the first layer and the ionization potential of the second layer is smaller than the difference between the electron affinity of the acceptor semiconductor material and the ionization potential of the donor semiconductor material in the photoelectric conversion layer. Thus, the configuration having the above relation between the electron affinity and the ionization potential can be readily achieved.

An imaging device according to an eleventh aspect of the present disclosure includes the photoelectric conversion element according to any one of the first to tenth aspects and a charge accumulation region that is electrically connected to the first electrode and that accumulates the signal charge.

The imaging device having the above-described configuration includes the above-described photoelectric conversion element, and thus parasitic sensitivity can be reduced.

In a twelfth aspect of the present disclosure, which is the imaging device according to the eleventh aspect, the imagining device may further include a voltage supply circuit that is electrically connected to the second electrode and that provides a potential difference between the first electrode and the second electrode. The voltage supply circuit may supply a first voltage to the second electrode in a first period and supply a second voltage that is different from the first voltage in a second period that is different from the first period.

The above-described configuration enables the timing of photoelectric conversion and the timing of readout to be separated by setting the first and second voltages depending on the characteristics of the photoelectric conversion element, and thus parasitic sensitivity can be further reduced.

Hereinafter, an embodiment will be described in detail with reference to the drawings.

The embodiments described below are all general or specific examples. The numbers, shapes, materials, components, positions of the components, connections between the components, steps, and the order of steps in the following embodiments are examples and should not be construed as limiting of the disclosure. Among the components of the embodiment described below, components that are not described in the independent claims, will be described as optional components.

The drawings are schematic views and are not necessarily accurate. Accordingly, in the drawings, components are not necessarily to scale. In the drawings, the same reference numerals are assigned to the components having substantially the same configuration without duplicated or detailed explanation.

In this specification, terms indicating relationships between components such as perpendicular, terms indicating shapes of components such as rectangular, and numerical ranges are not strictly limited to the meanings of the terms and the ranges. The terms and the ranges may include approximation, such as variations of a few percents.

In the specification, the terms “upper” and “lower” are not meant to refer to the upward direction (vertically upward) and the downward direction (vertically downward) in absolute spatial awareness. The terms are meant to refer to the relative positional relationship in the stack based on the stacking order. Furthermore, the terms “upper” and “lower” are used not only for a case where two components are spaced apart from each other with another component being interposed therebetween but also for a case where two adjacent components are in contact with each other.

In this specification, electromagnetic waves in general including visible light, infrared light, and ultraviolet light, are referred to as “light” for convenience.

### Embodiment

Hereinafter, an embodiment will be described.

### Photoelectric Conversion Element

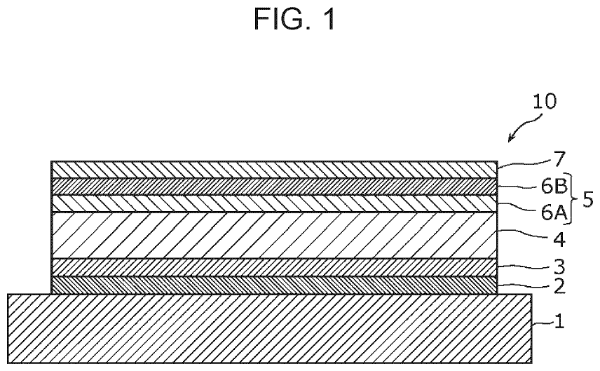

First, a photoelectric conversion element according to the present embodiment will be described. The photoelectric conversion element according to the present embodiment is a charge readout photoelectric conversion element. The photoelectric conversion element according to the present embodiment is used, for example, in an imaging device, an optical sensor, or an optical detector. FIG. 1 is a schematic cross-sectional view illustrating a configuration of a photoelectric conversion element 10 according to this embodiment.

As illustrated in FIG. 1, the photoelectric conversion element 10 is supported by a support substrate 1 and includes an upper electrode 7 and a lower electrode 2, which form a pair of electrodes, a photoelectric conversion layer 4 located between the upper electrode 7 and the lower electrode 2, a charge injection layer 5 located between the upper electrode 7 and the photoelectric conversion layer 4, an electron blocking layer 3 located between the lower electrode 2 and the photoelectric conversion layer 4. In this embodiment, the upper electrode 7 is an example of a second electrode, and the lower electrode 2 is an example of a first electrode.

Hereinafter, the components of the photoelectric conversion element 10 will be described below.

The support substrate 1 may be any substrate used to support a general photoelectric conversion element. Examples of the substrate include a glass substrate, a quartz substrate, a semiconductor substrate, and a plastic substrate.

The lower electrode 2 collects a signal charge generated in the photoelectric conversion layer 4. The lower electrode 2 is formed of, for example, metal, metal nitride, metal oxide, or conductivity-imparted polysilicon. Examples of the metal include aluminum, copper, titanium, and tungsten. An example of a method of imparting conductivity to polysilicon is doping with impurities.

The upper electrode 7 and the lower electrode 2 are opposed to each other with the photoelectric conversion layer 4 interposed therebetween. The upper electrode 7 is, for example, a transparent electrode formed of a transparent conductive material. Examples of the material of the upper electrode 7 include transparent conducting oxide (TCO), indium tin oxide (ITO), indium zinc oxide (IZO), aluminum-doped zinc oxide (AZO), fluorine-doped tin oxide (FTO), SnO₂, and TiO₂. The upper electrode 7 may be formed by using TCO and a metal material, such as aluminum (Al) and gold (Au), alone or in combination as appropriate, depending on the desired transmittance.

The materials of the lower electrode 2 and the upper electrode 7 are not limited to the conductive materials listed above, and other materials may be used. For example, the lower electrode 2 may be a transparent electrode.

Various methods are used to produce the lower electrode 2 and the upper electrode 7 depending on the materials used. For example, when ITO is used, the method may be an electron beam process, a sputtering process, a resistance heating vapor deposition method, a chemical reaction process such as a sol-gel process, or a coating process with indium tin oxide dispersion. In such a case, the lower electrode 2 and the upper electrode 7 may further undergo a UV-ozone treatment or a plasma treatment, after formation of the ITO film.

The photoelectric conversion layer 4 contains a donor semiconductor material and an acceptor semiconductor material. The photoelectric conversion layer 4 is formed, for example, by using an organic semiconductor material. The photoelectric conversion layer 4 may be formed, for example, by a wet method such as a spin-coating method or a dry method such as a vacuum deposition process. In the Vacuum deposition process, the material of the layer is heated under vacuum to be vaporized so that the material is deposited on the substrate. The charge injection layer 5 can also be formed by a similar method to the method used to form the photoelectric conversion layer 4.

The photoelectric conversion layer 4 is, for example, a mixed film having a bulk heterostructure containing a donor semiconductor material such as a donor organic semiconductor material and an acceptor semiconductor material such as an acceptor organic semiconductor material. The photoelectric conversion layer 4 may have a layered structure including a layer of a donor semiconductor material and a layer of an acceptor semiconductor material.

The photoelectric conversion layer 4 is readily formed as a thin film by including the donor organic semiconductor material and the acceptor organic semiconductor material. The following are specific examples of the donor and acceptor organic semiconductor materials.

Examples of the donor organic semiconductor material include triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, naphthalocyanine compounds, subphthalocyanine compounds, cyanine compounds, merocyanine compounds, oxonol compounds, polyamine compounds, indole compounds, pyrrole compounds, pyrazole compounds, polyarylene compounds, fused aromatic carbon ring compounds (such as naphthalene derivatives, anthracene derivatives, phenanthrene derivatives, tetracene derivatives, pyrene derivatives, perylene derivatives, and fluoranthene derivatives) and metal complexes having nitrogen-containing heterocyclic compounds as ligands. Examples of the donor organic semiconductor material are not limited to the above. Any organic compound that has a smaller ionization potential than the organic compound used as the acceptor organic semiconductor material may be used as the donor organic semiconductor material.

Examples of the acceptor organic semiconductor material include fullerene (such as C60 fullerene and C70 fullerene), fullerene derivatives (such as Phenyl-C61-Butyric Acid Methyl Ester (PCBM) and Indene-C60 Bisadduct (ICBA)), fused aromatic carbon ring compounds (such as naphthalene derivatives, anthracene derivatives, phenanthrene derivatives, tetracene derivatives, pyrene derivatives, perylene derivatives, and fluoranthene derivatives), 5- to 7-membered heterocyclic compounds containing nitrogen, oxygen, or sulfur atoms (such as pyridine, pyrazine, pyrimidine, pyridazine, triazine, quinoline, quinoxaline, quinazoline, phthalazine, sinoline, isoquinoline, pteridine, acridine, phenazine, phenanthroline, tetrazole, pyrazole, imidazole, thiazole, oxazole, indazole, benzimidazole, benzodriazole, benzoxazole, benzothiazole, carbazole, purine, triazolopyridazine, triazolopyrimidine, tetrazindene, oxadiazole, imidazopyridine, pyrrolidine, pyrrolopyridine, thiadiazolopyridine, dibenzazepine, and tribenzazepine), polyarylene compounds, fluorene compounds, cyclopentadiene compounds, silyl compounds, and metal complexes with nitrogen-containing heterocyclic compounds as ligands. Examples of the acceptor organic semiconductor material are not limited to the above. Any organic compound that has a larger electron affinity than the organic compound used as the donor organic semiconductor material may be used as the acceptor organic semiconductor material.

The donor and acceptor organic semiconductor materials are not limited to the above examples. An organic compound having a low molecular weight and an organic compound having a high molecular weight that can be deposited as a photoelectric conversion layer by either a dry method or a wet method may be used as the donor organic semiconductor material and the acceptor organic semiconductor material of the photoelectric conversion layer 4.

The photoelectric conversion layer 4 may contain a semiconductor material other than the above as the donor semiconductor material or the acceptor semiconductor material. The photoelectric conversion layer 4 may contain, as a semiconductor material, for example, a silicon semiconductor, a compound semiconductor, a quantum dot, a perovskite material, a carbon nanotube, or a mixture of any two or more of these.

The photoelectric conversion element 10 according to this embodiment includes the electron blocking layer 3 located between the lower electrode 2 and the photoelectric conversion layer 4 and the charge injection layer 5 located between the upper electrode 7 and the photoelectric conversion layer 4. The electron blocking layer 3 is in contact with, for example, the lower electrode 2 and the photoelectric conversion layer 4. The charge injection layer 5 is in contact with, for example, the upper electrode 7 and the photoelectric conversion layer 4. The electron blocking layer 3 is an optional component for the photoelectric conversion element 10.

The charge injection layer 5 includes a first layer 6A and a second layer 6B located on the first layer 6A. The first layer 6A and the second layer 6B are in contact with each other. In the photoelectric conversion element 10, the first layer 6A is located between the second layer 6B and the photoelectric conversion layer 4. The first layer 6A is in contact with the photoelectric conversion layer 4, for example. The second layer 6B is in contact with the upper electrode 7, for example.

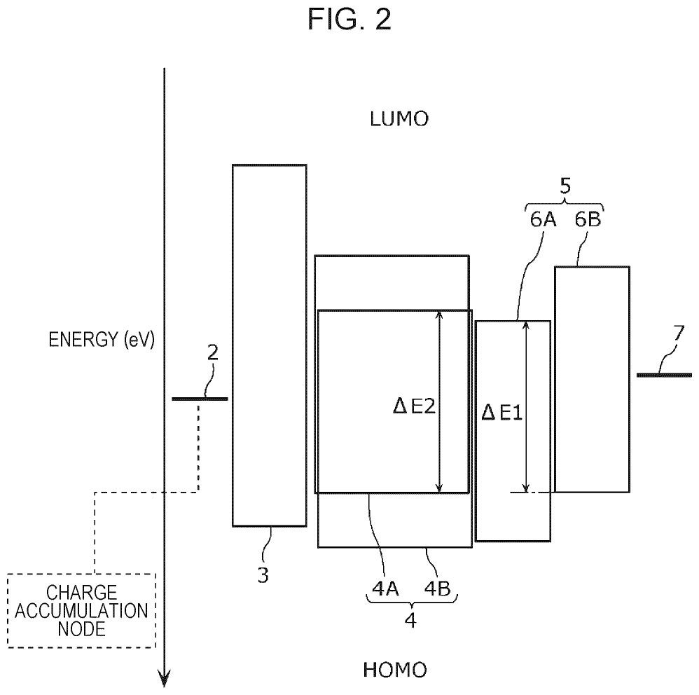

Here, the functions and other features of the electron blocking layer 3, the photoelectric conversion layer 4, and the charge injection layer 5 will be explained by using an energy band diagram. FIG. 2 is an exemplary energy band diagram of the photoelectric conversion element 10 illustrated in FIG. 1. In FIG. 2, the energy bands of the layers are indicated by rectangles.

The photoelectric conversion layer 4 generates pairs of electrons and holes in it when irradiated with light. In the photoelectric conversion element 10, the hole of the pair is collected by the lower electrode 2 and used as a signal charge to be read out. In other words, the photoelectric conversion layer 4 converts light into a signal charge. The signal charge may be an electron. An example where the signal charge is an electron will be given later.

The pairs of electrons and holes generated in the photoelectric conversion layer 4 are separated into electrons and holes by the electric field applied to the photoelectric conversion layer 4. The electrons and holes move toward the lower electrode 2 and the upper electrode 7, respectively, in accordance with the electric field. Here, the semiconductor material that donates the electrons, of the pair of electrons and holes generated by light absorption, to the other material is a donor semiconductor material, and the semiconductor material that accepts the electrons is an acceptor semiconductor material. When the photoelectric conversion layer 4 is irradiated with light, for example, the donor semiconductor material generates pairs of electrons and holes and donates the electrons to the acceptor semiconductor material. In this way, the electrons and the holes are readily separated.

FIG. 2 shows examples of energy bands when organic semiconductor materials are used as the donor and acceptor semiconductor materials. When two different organic semiconductor materials are used, which one is the donor semiconductor material and which one is the acceptor semiconductor material is determined by the relative positions of the Highest-Occupied-Molecular-Orbital (HOMO) and Lowest-Unoccupied-Molecular-Orbital (LUMO) energy levels of the two organic semiconductor materials at the contact interface. In FIG. 2, the upper end of the rectangle indicating the energy band corresponds to the LUMO energy level, and the lower end corresponds to the HOMO energy level. The energy difference between the vacuum level and the HOMO energy level is referred to as an ionization potential. The energy difference between the vacuum level and the LUMO energy level is referred to as an electron affinity. In this specification, the lower the position, the larger the electron affinity and the ionization potential in the energy band diagram in FIG. 2 and other figures. If the semiconductor material of the photoelectric conversion layer 4 is an inorganic semiconductor material, this can be understood by reading HOMO and LUMO as a valence band and a conduction band, respectively.

As indicated in FIG. 2, of the two kinds of organic semiconductor materials, one having the smaller LUMO energy level, or smaller electron affinity, is the donor organic semiconductor material 4A. Of the two kinds of organic semiconductor materials of the photoelectric conversion layer 4, one having the larger LUMO energy level, or larger electron affinity, is the acceptor organic semiconductor material 4B. In FIG. 2, the energy band of the donor organic semiconductor material 4A is slightly shifted from that of the acceptor organic semiconductor material 4B in the horizontal direction. However, the shift is only for ease of viewing and does not indicate the distribution of the donor organic semiconductor material 4A and the acceptor organic semiconductor material 4B in the photoelectric conversion layer 4.

The electron blocking layer 3, which is provided to reduce dark current caused by injection of the electrons from the lower electrode 2, reduces injection of electrons from the lower electrode 2 into the photoelectric conversion layer 4. This can reduce noise signals that adversely affect the S/N ratio. As illustrated in FIG. 2, to reduce the injection of electrons from the lower electrode 2 into the photoelectric conversion layer 4, the electron affinity of the material of the electron blocking layer 3 is smaller than the work function of the lower electrode 2 and the electron affinity of the acceptor organic semiconductor material 4B of the photoelectric conversion layer 4.

Furthermore, in the example indicated in FIG. 2, the ionization potential of the electron blocking layer 3 is larger than that of the donor organic semiconductor material 4A of the photoelectric conversion layer 4. The electron affinity of the electron blocking layer 3 is smaller than that of the donor organic semiconductor material 4A of the photoelectric conversion layer 4.

The material of the electron blocking layer 3 may be a semiconductor material exemplified as the donor semiconductor material above or a hole-transporting organic compound.

The first layer 6A and the second layer 6B of the charge injection layer 5 are an acceptor and a donor, respectively. The first layer 6A can function as an acceptor that accepts electrons from the second layer 6B, and the second layer 6B can function as a donor that donates electrons to the first layer 6A. Specifically, the ionization potential of the first layer 6A is larger than that of the second layer 6B, and the electron affinity of the first layer 6A is larger than that of the second layer 6B.

This causes thermal electronic excitation from the HOMO of the second layer 6B to the LUMO of the first layer 6A at the contact interface between the first layer 6A and the second layer 6B, and charges are generated regardless of the state of light application to the photoelectric conversion element 10. Such electronic excitation causes the first layer 6A to have electrons and the second layer 6B to have holes. In the charge injection layer 5, since the electron affinity of the first layer 6A is larger than that of the second layer 6B, the thermal electronic excitation at the above interface is more likely to occur than the thermal electronic excitation in the first layer 6A.

The difference ΔE1 between the electron affinity of the first layer 6A and the ionization potential of the second layer 6B is smaller than the difference ΔE2 between the electron affinity of the acceptor organic semiconductor material 4B and the ionization potential of the donor organic semiconductor material 4A. Since the energy difference at the interface between the first layer 6A and the second layer 6B is smaller than the energy difference at the interface between the donor organic semiconductor material 4A and the acceptor organic semiconductor material 4B, more charges are generated by thermal excitation in the charge injection layer 5 than in the photoelectric conversion layer 4. This facilitates the injection of electrons from the charge injection layer 5 into the photoelectric conversion layer 4.

The charge injection layer 5 may also function as a hole blocking layer to reduce dark current caused by injection of holes from the upper electrode 7. This can reduce noise signals that adversely affect the S/N ratio. To reduce the injection of holes from the upper electrode 7 into the photoelectric conversion layer 4, at least the ionization potential of the material of the first layer 6A is larger than the work function of the upper electrode 7 and the ionization potential of the donor organic semiconductor material 4A of the photoelectric conversion layer 4. In FIG. 2, the ionization potential of the second layer 6B is smaller than that of the acceptor organic semiconductor material 4B of the photoelectric conversion layer 4, but this should not be construed as a limitation. The ionization potential of the second layer 6B may be larger than or equal to that of the acceptor organic semiconductor material 4B of the photoelectric conversion layer 4.

The material of the first layer 6A may be a semiconductor material exemplified as the acceptor semiconductor material above or an electron-transporting organic compound. The material of the second layer 6B may be a semiconductor material exemplified as the donor semiconductor material above or a hole-transporting organic compound.

The material of the first layer 6A may be a material identical to the acceptor semiconductor material contained in the photoelectric conversion layer 4. The material of the second layer 6B may be a material identical to the donor semiconductor material contained in the photoelectric conversion layer 4. This configuration in which at least one of the first layer 6A or the second layer 6B contains a material identical to the material contained in the photoelectric conversion layer 4 enables production of the photoelectric conversion element 10 with fewer kinds of materials.

The first layer 6A may contain a material identical to the acceptor semiconductor material contained in the photoelectric conversion layer 4, and also the second layer 6B may contain a material identical to the donor semiconductor material contained in the photoelectric conversion layer 4. For example, the first layer 6A may be composed of the acceptor organic semiconductor material 4B, and the second layer 6B may be composed of the donor organic semiconductor material 4A. When the photoelectric conversion layer 4 is formed of a mixed film having a bulk heterostructure, the donor organic semiconductor material 4A and the acceptor organic semiconductor material 4B are less affected by stabilization than when the photoelectric conversion layer 4 is formed of a single material film, and the difference between the HOMO energy level and the LUMO energy level increases. Thus, even if the charge injection layer 5 and the photoelectric conversion layer 4 have the same composition of materials, the difference ΔE1 between the electron affinity of the first layer 6A and the ionization potential of the second layer 6B is smaller than the difference ΔE2 between the electron affinity of the acceptor organic semiconductor material 4B and the ionization potential of the donor organic semiconductor material 4A. Thus, a configuration in which ΔE1 is smaller than ΔE2 can be readily achieved.

Here, the driving of the photoelectric conversion element 10 will be described.

As illustrated in FIG. 2, for example, when the photoelectric conversion element 10 is used in an imaging device, the lower electrode 2 is electrically connected to a charge accumulation node, which will be described later. The charge accumulation node accumulates the holes generated in the photoelectric conversion layer 4 and collected by the lower electrode 2.

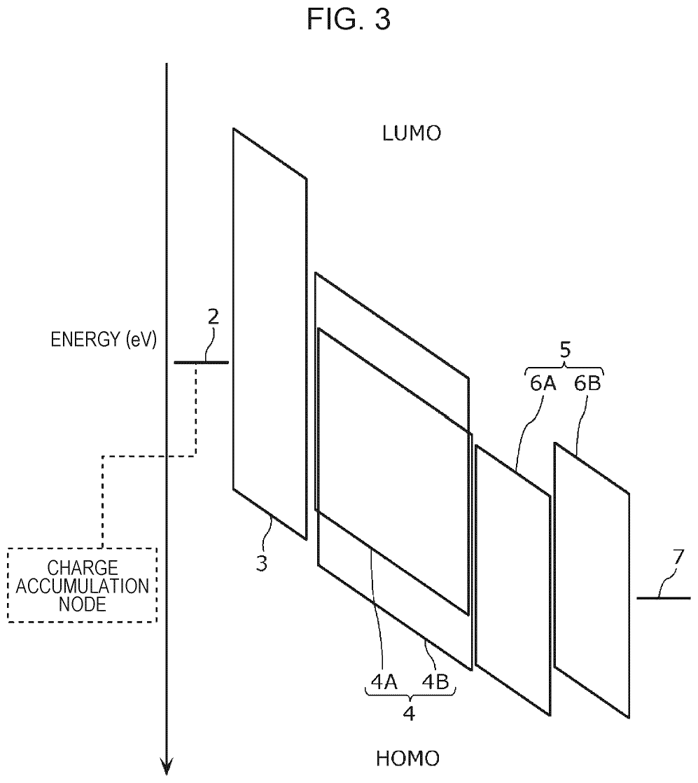

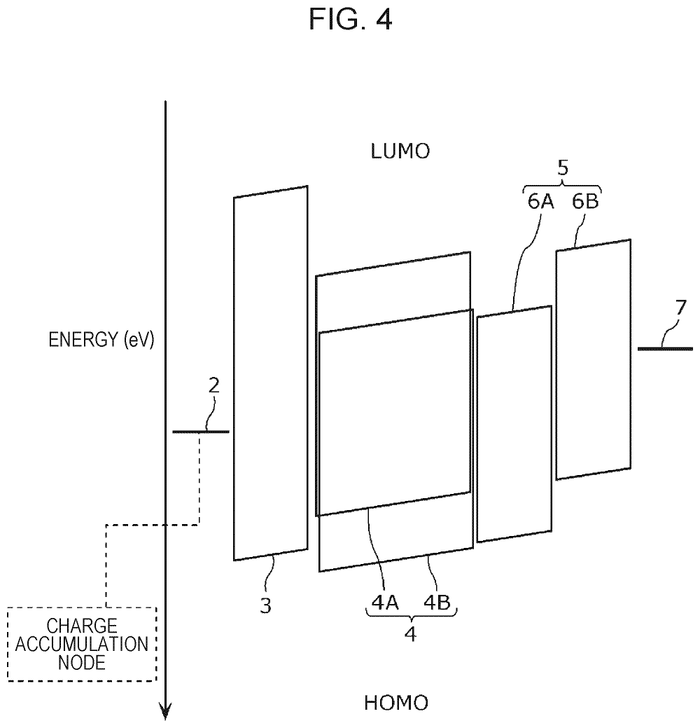

FIG. 3 is an exemplary energy band diagram of the photoelectric conversion element 10 when a reverse bias voltage is applied between the lower electrode 2 and the upper electrode 7. FIG. 4 is an exemplary energy band diagram of the photoelectric conversion element 10 when a forward bias voltage is applied between the lower electrode 2 and the upper electrode 7. In this specification, when the signal charge is a hole, a voltage that is applied between the upper electrode 7 and the lower electrode 2 such that the potential of the upper electrode 7 becomes higher than that of the lower electrode 2 is reverse biasing or the so-called reverse bias voltage. In this specification, when the signal charge is a hole, a voltage that is applied between the upper electrode 7 and the lower electrode 2 such that the potential of the upper electrode 7 becomes lower than that of the lower electrode 2 is forward biasing or the so-called forward bias voltage.

The photoelectric conversion element 10 is driven switchably, for example, between a photoelectric conversion mode and a signal readout mode. In the photoelectric conversion mode, a reverse bias voltage is applied between the upper electrode 7 and the lower electrode 2, as indicated in FIG. 3. The absolute value of the voltage in this case is, for example, from about 1 V to about 10 V. In the signal readout mode, a forward bias voltage is applied between the upper electrode 7 and the lower electrode 2, as indicated in FIG. 4. The absolute value of the voltage in this case is, for example, from 0 V to about 3 V.

For example, during the photoelectric conversion mode indicated in FIG. 3, pairs of electrons and holes are generated in the photoelectric conversion layer 4 when light is incident on the photoelectric conversion layer 4. Of the generated electrons and holes, holes, which are signal charges, move to the lower electrode 2, and electrons, which are charges of opposite polarity to the signal charges, move to the upper electrode 7. The holes moved to the lower electrode 2 are accumulated in the charge accumulation node, for example. Then, during the signal readout mode indicated in FIG. 4, signals based on the holes accumulated in the charge accumulation node through the lower electrode 2 are read out.

In this case, in the photoelectric conversion mode, when holes move from the photoelectric conversion layer 4 to the lower electrode 2, the holes may fail to move to the lower electrode 2 within the photoelectric conversion mode period and may remain in the photoelectric conversion layer 4 in the signal readout mode. The photoelectric conversion layer 4 including an organic semiconductor material tends to have a decreased charge mobility, and thus holes are particularly likely to remain in the photoelectric conversion layer 4. Thus, if holes remaining in the photoelectric conversion layer 4 move to the lower electrode 2 after the transition from the photoelectric conversion mode to the signal readout mode, the holes appear as parasitic sensitivity, which is unintended sensitivity and a possible cause of noise. In the photoelectric conversion element 10, electrons are likely to be present in the first layer 6A due to thermal electronic excitation at the interface between the first layer 6A and the second layer 6B described above, and the electrons move toward the lower electrode 2 where they recombine with the holes remaining in the photoelectric conversion layer 4. This reduces migration of the holes remaining in the photoelectric conversion layer 4 to the lower electrode 2 during the signal readout mode. Thus, parasitic sensitivity caused by the migration of the holes remaining in the photoelectric conversion layer 4 to the lower electrode 2 is reduced. In particular, since the first layer 6A is located between the second layer 6B and the photoelectric conversion layer 4, the second layer 6B does not act as a barrier to migration of electrons to the photoelectric conversion layer 4, and thus the electrons in the first layer 6A can readily move to the photoelectric conversion layer 4. Even when the second layer 6B is located between the first layer 6A and the photoelectric conversion layer 4, the electrons in the first layer 6A can move to the photoelectric conversion layer 4, thus providing the effect of reducing parasitic sensitivity.

As described above, the photoelectric conversion element 10 according to the embodiment includes the photoelectric conversion layer 4 and the charge injection layer 5 having the above-described energy band structures. In this configuration, when a signal is read out based on a hole, which is a signal charge, an electron is injected from the charge injection layer 5 into the photoelectric conversion layer 4, and a hole remaining in the photoelectric conversion layer 4 recombines with the injected electron. Thus, the holes remaining in the photoelectric conversion layer 4 are less likely to move to the lower electrode 2 during signal readout, effectively reducing parasitic sensitivity in the method of reading out holes from the lower electrode 2.

### Another Example of Photoelectric Conversion Element

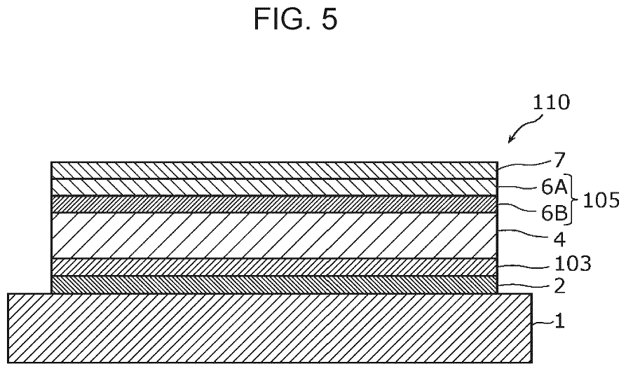

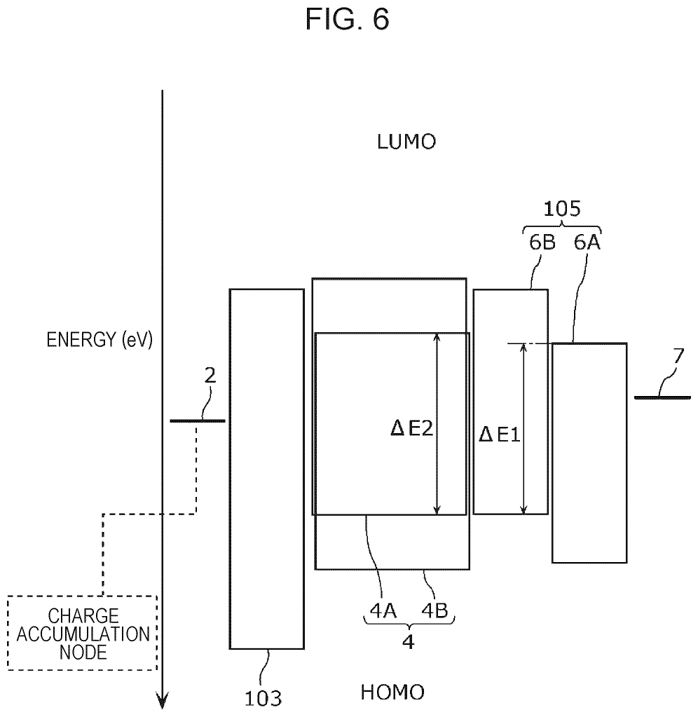

In the example described above, the signal charge collected by the lower electrode 2 is a hole. However, the signal charge may be an electron. Hereinafter, with reference to FIGS. 5 and 6, another photoelectric conversion element according to the present embodiment that uses an electron as the signal charge will be described.

FIG. 5 is a schematic cross-sectional view illustrating a configuration of another photoelectric conversion element 110 according to the present embodiment. FIG. 6 is an exemplary energy band diagram of the photoelectric conversion element 110 illustrated in FIG. 5. The following description will focus on the difference between the photoelectric conversion element 110 and the photoelectric conversion element 10, and overlapping description will be omitted or simplified.

As illustrated in FIGS. 5 and 6, the photoelectric conversion element 110 differs from the above-described photoelectric conversion element 10 in that the photoelectric conversion element 110 includes a hole blocking layer 103 and a charge injection layer 105 instead of the electron blocking layer 3 and the charge injection layer 5. Specifically, the photoelectric conversion element 110 is supported by the support substrate 1 and includes a pair of electrodes, which are the upper and lower electrodes 7 and 2, the photoelectric conversion layer 4 located between the upper electrode 7 and the lower electrode 2, the charge injection layer 105 located between the upper electrode 7 and the photoelectric conversion layer 4, and the hole blocking layer 103 located between the lower electrode 2 and the photoelectric conversion layer 4. The hole blocking layer 103 is an optional component for the photoelectric conversion element 110.

The charge injection layer 105 is the same as the charge injection layer 5 in that the charge injection layer 105 includes the first layer 6A and the second layer 6B, but the positions of the first layer 6A and the second layer 6B are swapped with those of the charge injection layer 5. In the photoelectric conversion element 110, the second layer 6B is located between the first layer 6A and the photoelectric conversion layer 4. The first layer 6A is in contact with, for example, the upper electrode 7. The second layer 6B is in contact with, for example, the photoelectric conversion layer 4.

The hole blocking layer 103, which is provided to reduce dark current caused by the injection of holes from the lower electrode 2, reduces injections of holes into the photoelectric conversion layer 4 from the lower electrode 2. This can reduce noise signals that adversely affect the S/N ratio. As indicated in FIG. 6, to reduce injection of holes into the photoelectric conversion layer 4 from the lower electrode 2, the ionization potential of the material of the hole blocking layer 103 is larger than the work function of the lower electrode 2 and the ionization potential of the donor organic semiconductor material 4A of the photoelectric conversion layer 4.

In the example indicated in FIG. 6, the electron affinity of the hole blocking layer 103 is smaller than that of the acceptor organic semiconductor material 4B of the photoelectric conversion layer 4. Furthermore, the ionization potential of the hole blocking layer 103 is larger than that of the acceptor organic semiconductor material 4B of the photoelectric conversion layer 4.

The material of the hole blocking layer 103 may be a semiconductor material exemplified as the acceptor semiconductor material above or an electron-transporting organic compound.

As in the photoelectric conversion element 10, in the photoelectric conversion element 110, the ionization potential of the first layer 6A is larger than that of the second layer 6B, and the electron affinity of the first layer 6A is larger than that of the second layer 6B. The difference ΔE1 between the electron affinity of the first layer 6A and the ionization potential of the second layer 6B is smaller than the difference ΔE2 between the electron affinity of the acceptor organic semiconductor material 4B and the ionization potential of the donor organic semiconductor material 4A. This facilitates the injection of holes from the charge injection layer 105 into the photoelectric conversion layer 4.

The charge injection layer 105 may also function as an electron blocking layer to reduce dark current caused by injection of electrons from the upper electrode 7. This can reduce noise signals that adversely affect the S/N ratio. To reduce injection of electrons into the photoelectric conversion layer 4 from the upper electrode 7, at least the electron affinity of the material of the second layer 6B is larger than the work function of the upper electrode 7 and the electron affinity of the acceptor organic semiconductor material 4B of the photoelectric conversion layer 4. In FIG. 6, the electron affinity of the first layer 6A is larger than that of the donor organic semiconductor material 4A of the photoelectric conversion layer 4, but this should not be construed as a limitation. The electron affinity of the first layer 6A may be equal to or smaller than that of the donor organic semiconductor material 4A of the photoelectric conversion layer 4.

In this specification, when the signal charge is an electron, a voltage that is applied between the upper electrode 7 and the lower electrode 2 such that the potential of the upper electrode 7 becomes lower than that of the lower electrode 2 is reverse biasing or the so-called reverse bias voltage. Furthermore, in this specification, when the signal charge is an electron, a voltage that is applied between the upper electrode 7 and the lower electrode 2 such that the potential of the upper electrode 7 becomes higher than that of the lower electrode 2 is forward biasing or the so-called forward bias voltage. Thus, the polarity is inverted between the photoelectric conversion element 10 and the photoelectric conversion element 110, even when the bias voltages are in the same direction.

When the photoelectric conversion element 110 is in the photoelectric conversion mode, pairs of electrons and holes are generated in the photoelectric conversion layer 4 when light is incident on the photoelectric conversion layer 4. Of the generated electrons and holes, electrons, which are signal charges, move to the lower electrode 2, and holes, which are charges of opposite polarity to the signal charges, move to the upper electrode 7. Then, when the photoelectric conversion element 110 is in the signal readout mode, signals based on the electrons accumulated in the charge accumulation node through the lower electrode 2 are read out.

In this case, during the photoelectric conversion mode, when electrons move from the photoelectric conversion layer 4 to the lower electrode 2, the electrons may fail to move to the lower electrode 2 within the photoelectric conversion mode period and may remain in the photoelectric conversion layer 4 during the signal read out mode. Thus, if the electrons remaining in the photoelectric conversion layer 4 move to the lower electrode 2 after the transition from the photoelectric conversion mode to the signal readout mode, the holes appear as parasitic sensitivity, which is unintended sensitivity and a possible cause of noise. In the photoelectric conversion element 110, holes are likely to be present in the second layer 6B due to thermal electronic excitation at the interface between the first layer 6A and the second layer 6B, and these holes move toward the lower electrode 2 where they recombine with the electrons remaining in the photoelectric conversion layer 4. This reduces migration of the electrons remaining in the photoelectric conversion layer 4 to the lower electrode 2 during the signal readout mode. Thus, parasitic sensitivity caused by the electrons remaining in the photoelectric conversion layer 4 is reduced. In particular, since the second layer 6B is located between the first layer 6A and the photoelectric conversion layer 4, the first layer 6A does not act as a barrier to migration of holes to the photoelectric conversion layer 4, and thus the holes in the second layer 6B can readily move to the photoelectric conversion layer 4. Even when the first layer 6A is located between the second layer 6B and the photoelectric conversion layer 4, holes in the second layer 6B can move to the photoelectric conversion layer 4, thus providing the effect of reducing parasitic sensitivity.

### Imaging Device

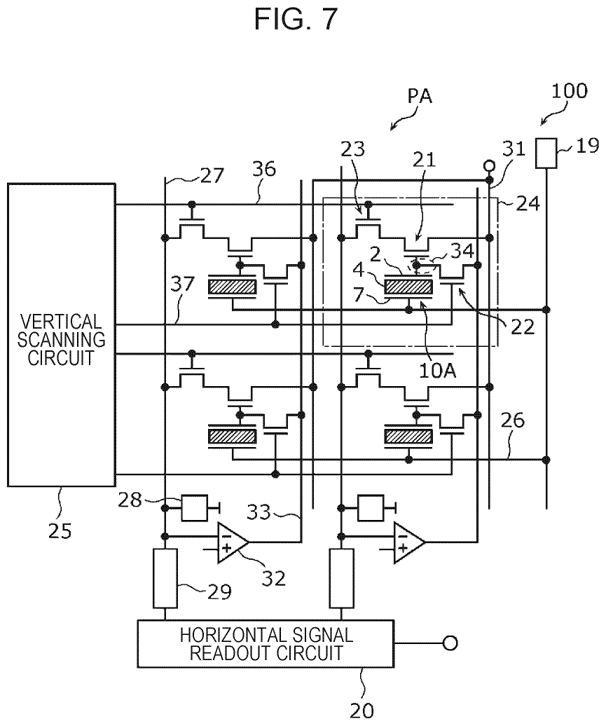

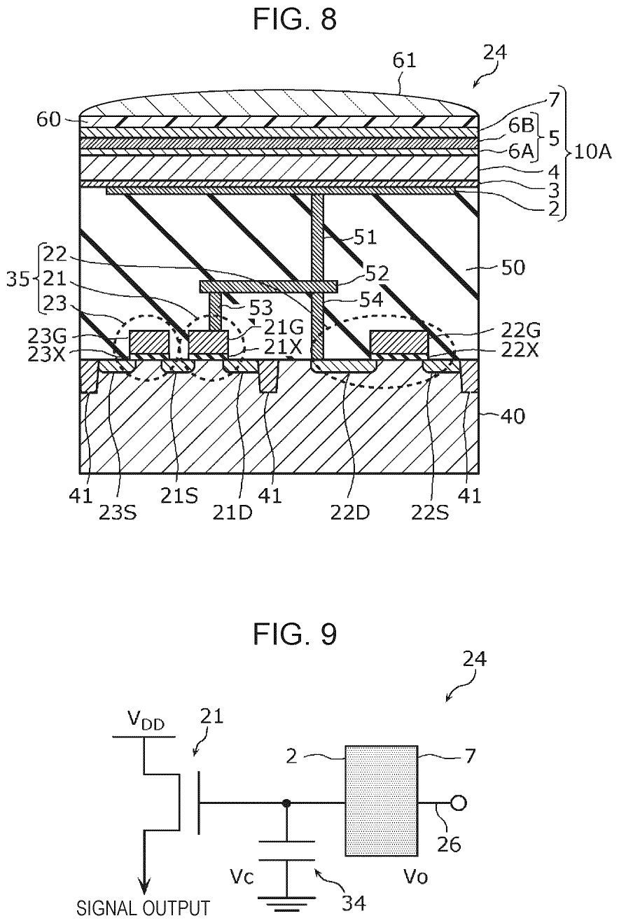

Next, an imaging device using the photoelectric conversion element according to the embodiment will be described with reference to FIGS. 7 and 8. FIG. 7 illustrates an example of circuitry of an imaging device 100 equipped with a photoelectric converter 10A including the photoelectric conversion element 10 illustrated in FIG. 1. FIG. 8 is a schematic cross-sectional view illustrating an example of a device structure of a pixel 24 in the imaging device 100 according to this embodiment. FIG. 7 illustrates the lower electrode 2, the photoelectric conversion layer 4, and the upper electrode 7 of the photoelectric converter 10A as representative components and does not illustrate the electron blocking layer 3 and the charge injection layer 5.

As illustrated in FIGS. 7 and 8, the imaging device 100 according to this embodiment includes the pixels 24 each including a semiconductor substrate 40, a charge detection circuit 35 provided at the semiconductor substrate 40, the photoelectric converter 10A provided on the semiconductor substrate 40, and a charge accumulation node 34 electrically connected to the charge detection circuit 35 and the photoelectric converter 10A. The photoelectric converters 10A of the pixels 24 are each composed of the photoelectric conversion element 10 described above. Specifically, the pixels 24 each include the photoelectric converter 10A including the upper electrode 7, the lower electrode 2, the photoelectric conversion layer 4, the charge injection layer 5, and the electron blocking layer 3. In this embodiment, the charge accumulation node 34 is an example of the charge accumulation region. In the following example, the photoelectric converter 10A has the same configuration as the photoelectric conversion element 10, and the signal charge is a hole. The photoelectric converter 10A may have the same configuration as the photoelectric conversion element 110, and the signal charge may be an electron.

The charge accumulation node 34 accumulates signal charges generated in the photoelectric converter 10A, and the charge detection circuit 35 detects the signal charges accumulated in the charge accumulation node 34. The charge detection circuit 35 provided at the semiconductor substrate 40 may be located on the semiconductor substrate 40 or located in the semiconductor substrate 40.

As illustrated in FIG. 7, the imaging device 100 has the pixels 24 and peripheral circuits. The imaging device 100 is an image sensor including a single-chip integrated circuit and has a pixel array PA having the pixels 24 arranged in two dimensions. The imaging device 100 is, for example, an imaging device that operates with a global shutter system in which an exposure period is the same for all the multiple pixels 24. In short, the imaging device 100 has a global shutter function. The exposure period will be described in detail later.

The pixels 24 are arranged on the semiconductor substrate 40 in two dimensions, i.e., in the row and column directions, to form a photosensitive area, which is a pixel area. In an example of FIG. 7, the pixels 24 are arranged in a matrix of two rows and two columns. For convenience of illustration, FIG. 7 does not illustrate a circuit for setting the sensitivity of each of the pixels 24 (e.g., pixel electrode control circuit). The imaging device 100 may be a line sensor. In such a case, the pixels 24 may be arranged in one dimension. In this specification, the row direction extends along the row, and the column direction extends along the column. In this specification, the horizontal direction corresponds to the row direction, and the vertical direction corresponds to the column direction.

As illustrated in FIGS. 7 and 8, each pixel 24 has the photoelectric converter 10A and the charge accumulation node 34 electrically connected to the charge detection circuit 35. The charge detection circuit 35 includes an amplifier transistor 21, a reset transistor 22, and an address transistor 23.

The photoelectric converter 10A includes the lower electrode 2 as a pixel electrode and the upper electrode 7 as a counter electrode. A voltage for application of a predetermined bias voltage is supplied to the upper electrode 7 through a counter electrode signal line 26.

The lower electrode 2 is connected to a gate electrode 21G of the amplifier transistor 21, and signal charges collected by the lower electrode 2 are accumulated in the charge accumulation node 34 located between the lower electrode 2 and the gate electrode 21G of the amplifier transistor 21. The charge accumulation node 34 is electrically connected to the lower electrode 2 and accumulates holes, which are signal charges generated in the photoelectric conversion layer 4.

The voltage corresponding to the amount of signal charges accumulated in the charge accumulation node 34 is applied to the gate electrode 21G of the amplifier transistor 21. The amplifier transistor 21 amplifies this voltage, and the address transistor 23 selectively reads out this voltage as a signal voltage. The reset transistor 22, the source/drain electrode of which is connected to the lower electrode 2 via the charge accumulation node 34, resets the signal charges accumulated in the charge accumulation node 34. In other words, the reset transistor 22 resets the potentials of the gate electrode 21G of the amplifier transistor 21 and the lower electrode 2.

To selectively perform the operations described above in the pixels 24, the imaging device 100 has a power line 31, a vertical signal line 27, an address signal line 36, and a reset signal line 37. These lines are connected to each pixel 24. Specifically, the power line 31 is connected to the source/drain electrode of the amplifier transistor 21, and the vertical signal line 27 is connected to the source/drain electrode of the address transistor 23. The address signal line 36 is connected to a gate electrode 23G of the address transistor 23. The reset signal line 37 is connected to a gate electrode 22G of the reset transistor 22.

The peripheral circuits include a voltage supply circuit 19, a vertical scanning circuit 25, a horizontal signal readout circuit 20, multiple column signal processing circuits 29, multiple load circuits 28, and multiple differential amplifiers 32.

The voltage supply circuit 19 is electrically connected to the upper electrode 7 via the counter electrode signal line 26. The voltage supply circuit 19 provides a potential difference between the upper electrode 7 and the lower electrode 2 by supplying a voltage to the upper electrode 7. The voltage supply circuit 19, for example, supplies a first voltage to the upper electrode 7 during a first period, such as an exposure period described below, and supplies a second voltage different from the first voltage during a second period different from the first period, such as a non-exposure period.

The vertical scanning circuit 25, which is connected to the address signal line 36 and the reset signal line 37, selects the pixels 24 arranged in a column by row and row, reads out signal voltages, and resets the potentials of the lower electrodes 2. The power line 31 serving as a source follower power source supplies a predetermined power-source voltage to each of the pixels 24. The horizontal signal readout circuit 20 is electrically connected to the multiple column signal processing circuits 29. The column signal processing circuit 29 is electrically connected to the pixels 24 arranged in each row via the vertical signal lines 27 corresponding to the rows. The load circuits 28 are electrically connected to the corresponding vertical signal lines 27. The load circuit 28 and the amplifier transistor 21 form a source follower circuit.

The differential amplifiers 32 are provided for corresponding rows. The differential amplifiers 32 each have a negative input terminal connected to the corresponding vertical signal line 27. The output terminal of the differential amplifier 32 is connected to the pixels 24 through a feedback line 33 corresponding to one of the rows.

The vertical scanning circuit 25 applies a column selection signal for controlling on/off of the address transistor 23 to the gate electrode 23G of the address transistor 23 through the address signal line 36. Thus, the column to be read out is scanned and selected. From the pixels 24 of the selected column, signal voltages are read out to the vertical signal line 27. In addition, the vertical scanning circuit 25 applies a reset signal for controlling on/off of the reset transistor 22 to the gate electrode 22G of the reset transistor 22 through the reset signal line 37. Thus, the column of the pixels 24 to be subjected to the reset operation is selected. The vertical signal line 27 transmits the signal voltage read out from the pixels 24 selected by the vertical scanning circuit 25 to the column signal processing circuit 29.

The column signal processing circuit 29 performs, for example, a noise reducing signal processing represented by correlated double sampling and analog-digital conversion (AD conversion).

The horizontal signal readout circuit 20 sequentially reads out signals from the multiple column signal processing circuits 29 to a horizontal common signal line.

The differential amplifier 32 is connected to the drain electrode of the reset transistor 22 via the feedback line 33. Thus, the differential amplifier 32 receives the output value of the address transistor 23 at its negative terminal. The differential amplifier 32 performs feedback operation such that the gate potential of the amplifier transistor 21 becomes a predetermined feedback voltage. At this time, the output voltage value of the differential amplifier 32 is 0 V or a positive voltage close to 0 V. The feedback voltage means the output voltage of the differential amplifier 32.

As illustrated in FIG. 8, the pixel 24 includes the semiconductor substrate 40, the charge detection circuit 35, the photoelectric converter 10A, and the charge accumulation node 34 (see FIG. 7).

The semiconductor substrate 40 may be an insulating substrate having a semiconductor layer on the side where the photosensitive area is formed, for example, a p-type silicon substrate. The semiconductor substrate 40 has impurity regions 21D, 21S, 22D, 22S, and 23S and an isolation region 41 for electrical isolation between the pixels 24. The impurity regions 21D, 21S, 22D, 22S, and 23S are, for example, n-type regions. Here, the isolation region 41 is disposed between the impurity region 21D and the impurity region 22D. This reduces leakage of signal charges accumulated in the charge accumulation node 34. The isolation region 41 is formed, for example, by implantation of acceptor ions under predetermined injection conditions.

The impurity regions 21D, 21S, 22D, 22S and 23S are, for example, diffusion regions in the semiconductor substrate 40. As illustrated in FIG. 8, the amplifier transistor 21 includes the impurity regions 21S and 21D and the gate electrode 21G. The impurity regions 21S and 21D act as, for example, the source and drain regions of the amplifier transistor 21, respectively. A channel region of the amplifier transistor 21 is formed between the impurity region 21S and the impurity region 21D.

Similarly, the address transistor 23 includes the impurity regions 23S and 21S and the gate electrode 23G connected to the address signal line 36. In this example, the amplifier transistor 21 and the address transistor 23 are electrically connected to each other by sharing the impurity region 21S. The impurity region 23S acts as, for example, a source region of the address transistor 23. The impurity region 23S has a connection to the vertical signal line 27 illustrated in FIG. 7.

The reset transistor 22 includes the impurity regions 22D and 22S, and the gate electrode 22G connected to the reset signal line 37. The impurity region 22S serves, for example, as a source region of the reset transistor 22. The impurity region 22S has a connection to the reset signal line 37 illustrated in FIG. 7.

An interlayer insulating layer 50 is disposed on the semiconductor substrate 40 to cover the amplifier transistor 21, the address transistor 23, and the reset transistor 22. In FIG. 8, for ease of viewing, the interlayer insulating layer 50 does not have hatching indicating that the layer is in a cross section.

Furthermore, a wiring layer (not illustrated) may be included in the interlayer insulating layer 50. The wiring layer is formed, for example, of a metal such as copper, and can include, for example, wiring such as the above-described vertical signal line 27 as a portion thereof. The number of insulating layers in the interlayer insulating layer 50 and the number of layers included in the wiring layer included in the interlayer insulating layer 50 may be appropriately set.

In the interlayer insulating layer 50, a contact plug 53 connected to the gate electrode 21G of the amplifier transistor 21, a contact plug 54 connected to the impurity region 22D of the reset transistor 22, a contact plug 51 connected to the lower electrode 2, and a wiring line 52 connecting the contact plug 51, the contact plug 54, and the contact plug 53 are disposed. This allows the impurity region 22D of the reset transistor 22 to be electrically connected to the gate electrode 21G of the amplifier transistor 21. In the configuration illustrated in FIG. 8, the contact plugs 51, 53, and 54, the wiring line 52, the gate electrode 21G of the amplifier transistor 21, and the impurity region 22D of the reset transistor 22 constitute at least a portion of the charge accumulation node 34.

The charge detection circuit 35 detects signal charges captured by the lower electrode 2 and outputs a signal voltage. The charge detection circuit 35 includes the amplifier transistor 21, the reset transistor 22, and the address transistor 23 and is on the semiconductor substrate 40.

The amplifier transistor 21 includes the impurity regions 21D and 21S, which are in the semiconductor substrate 40 and act as a drain electrode and a source electrode, respectively, a gate insulating layer 21X on the semiconductor substrate 40, and the gate electrode 21G on the gate insulating layer 21X.

The reset transistor 22 includes the impurity regions 22D and 22S, which are in the semiconductor substrate 40 and act as a drain electrode and a source electrode, respectively, a gate insulating layer 22X on the semiconductor substrate 40, and the gate electrode 22G on the gate insulating layer 22X.

The address transistor 23 includes the impurity regions 21S and 23S, which are in the semiconductor substrate 40 and act as a drain electrode and a source electrode, respectively, a gate insulating layer 23X on the semiconductor substrate 40, and the gate electrode 23G on the gate insulating layer 23X. The impurity region 21S is connected in series with the amplifier transistor 21 and the address transistor 23.

The photoelectric converter 10A described above is disposed on the interlayer insulating layer 50. In other words, in this embodiment, the pixels 24 constituting the pixel array PA are formed over the semiconductor substrate 40. The pixels 24 arranged in two dimensions over the semiconductor substrate 40 form the photosensitive area. The distance between two adjacent pixels 24 (pixel pitch) may be, for example, about 2 μm.

A color filter 60 is formed on the photoelectric converter 10A, and a microlens 61 is formed on the color filter 60. The color filter 60 is formed, for example, as an on-chip color filter by patterning using a photosensitive resin containing a dye or a pigment in a dispersed state. The microlens 61 is formed, for example, as an on-chip microlens and is formed of, for example, a UV-photosensitive material.

The imaging device 100 can be produced by a common semiconductor manufacturing process. In particular, when the semiconductor substrate 40 is a silicon substrate, various silicon semiconductor processes are available for the production.

### Operation of Imaging Device

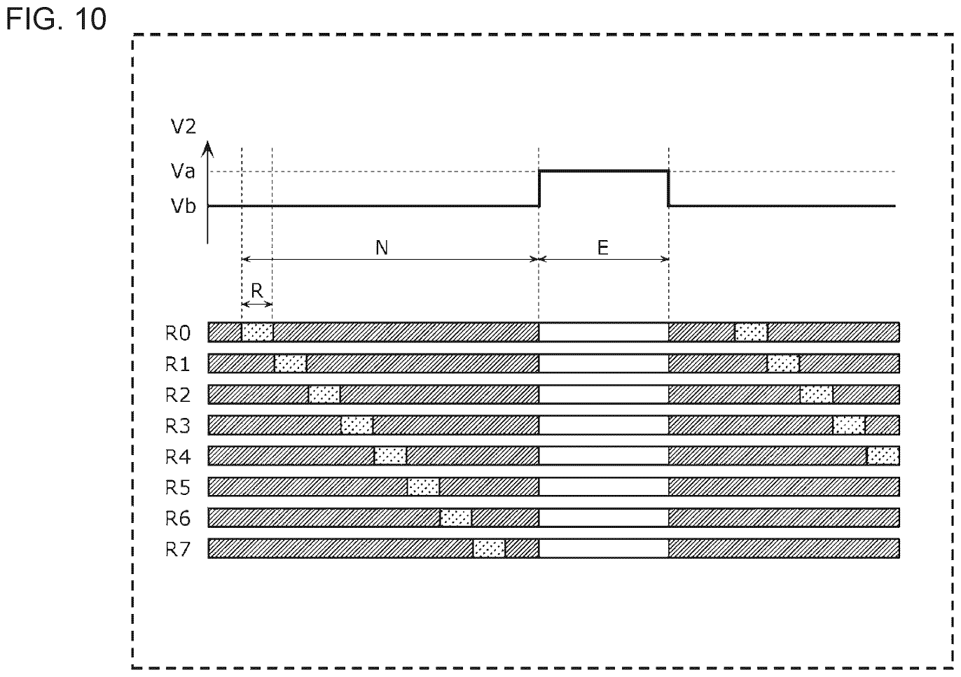

Next, the operation of the imaging device 100 will be described with reference to FIGS. 9 and 10. In the following description of the operation of the imaging device 100, holes are used as signal charges as described above.

FIG. 9 schematically illustrates a portion of the circuitry of the pixel 24. For simplicity of explanation, in this example, one end of the charge accumulation node 34 is grounded, and the potential is zero. This state corresponds, for example, to the state where the feedback line 33 indicated in FIG. 7 is set at 0 V. In this state, if the voltage at the charge accumulation node 34 is Vc, Vc is zero.

The voltage supply circuit 19 illustrated in FIG. 7 supplies different voltages to the upper electrode 7 during the exposure period, which is an example of the first period, and during the non-exposure period, which is an example of the second period, through the counter electrode signal line 26. In this specification, the “exposure period” means the period for accumulating one of the electron and the hole generated by photoelectric conversion as a signal charge in the charge accumulation node 34. In other words, the “exposure period” may be called the “charge accumulation period”. In this specification, the period of time during which the imaging device 100 is in operation but not in the exposure period is referred to as the “non-exposure period”. The “non-exposure period” may be a period during which light is not incident on the photoelectric converter 10A, or a period during which the photoelectric converter 10A is irradiated with light but charge is not substantially accumulated in the charge accumulation node 34.

For example, when the imaging device 100 is driven, a bias voltage in a first voltage range or a second voltage range is applied to the photoelectric converter 10A.

In the first voltage range, a change in current of the photoelectric conversion layer 4 less depends on the bias voltage applied between the lower electrode 2 and the upper electrode 7 and on the amount of light incident on the photoelectric conversion layer 4 than in the second voltage range. In other words, in the first voltage range, the difference between the value of current flowing when light is incident on the photoelectric conversion layer 4 and the value of current flowing when light is not incident on the photoelectric conversion layer 4 can be considered small. In the first voltage range, even if pairs of holes and electrons are generated by light incident on the photoelectric conversion layer 4, the absolute value of the voltage applied between the lower electrode 2 and the upper electrode 7 is not large, and thus the holes and electrons are likely to recombine before they are separated. The first voltage range includes, for example, a forward bias voltage range.

In the second voltage range, the current value increases as the amount of light incident on the photoelectric conversion layer 4 and the bias voltage applied between the lower electrode 2 and the upper electrode 7 increase.

In the initial state, the potential difference between the lower electrode 2 and the upper electrode 7 of the photoelectric converter 10A, that is, the bias voltage applied to the photoelectric conversion layer 4, the electron blocking layer 3, and the charge injection layer 5, is set within the first voltage range. For example, the voltage supply circuit 19 supplies a voltage equal to the voltage of the lower electrode 2 to the upper electrode 7 using the counter electrode signal line 26. Here, if the voltage supplied to the upper electrode 7 is V2, V2 is the reference voltage Vref. In this case, if the bias voltage applied to the photoelectric converter 10A is Vo, Vo=V2−Vc, and Vo=0.

Next, the operation in the exposure period will be described. At the beginning of the exposure period, the voltage supply circuit 19 supplies the voltage V2 to the upper electrode 7 using the counter electrode signal line 26 such that a bias voltage of a value within the second voltage range, or a reverse bias voltage, is applied to the photoelectric converter 10A. In other words, during the exposure period, the voltage supply circuit 19 supplies the voltage V2 that allows the photoelectric conversion layer 4 to have sensitivity of photoelectric conversion to the upper electrode 7. The voltage V2 supplied by the voltage supply circuit 19 during the exposure period is an example of the first voltage. For example, if the photoelectric conversion layer 4 is composed of an organic semiconductor material, the voltage V2 is a few V to about 10 V. This enables accumulation of holes, as signal charges, in the charge accumulation node 34 of each pixel 24 in an amount corresponding to the amount of light incident on the photoelectric conversion layer 4.

Next, the operation in the non-exposure period will be described. After the end of the exposure period, the voltage supply circuit 19 supplies the voltage V2 to the upper electrode 7 using the counter electrode signal line 26 such that a voltage within the first voltage range is applied to the photoelectric converter 10A. In other words, during the non-exposure period, the voltage supply circuit 19 supplies the voltage V2 that allows recombination of the electrons and holes with the photoelectric conversion layer 4 to the upper electrode 7. The voltage V2 supplied by the voltage supply circuit 19 during the non-exposure period is an example of the second voltage. For example, the voltage V2 supplied to the upper electrode 7 is set as the reference voltage Vref. In the charge accumulation node 34 of each pixel 24, holes are accumulated in an amount corresponding to the amount of light incident on the photoelectric conversion layer 4 during the exposure period, and the value of Vc varies among the pixels 24. Since Vo=V2−Vc, Vo is zero at the pixel 24 where Vc remains unchanged without exposure. However, Vo is not zero and is a forward bias voltage at the pixel 24 where Vc has changed.

With the voltage V2 within the first voltage range being supplied to the upper electrode 7, holes are unlikely to move to the charge accumulation node 34 even if light is incident on the pixel 24. In other words, the voltage supply circuit 19 supplies a voltage to the upper electrode 7 such that the photoelectric conversion efficiency of the pixels 24, specifically the photoelectric converters 10A, varies between the exposure period and the non-exposure period. With the voltage V2 within the first voltage range being supplied to the upper electrode 7, holes accumulated in the charge accumulation node 34 are unlikely to be discharged to the lower electrode 2 or charges supplied by the voltage supply circuit 19 through the lower electrode 2 are unlikely to flow into the charge accumulation node 34.

Accordingly, the holes accumulated in the charge accumulation node 34 of each pixel 24 are retained in an amount corresponding to the amount of light incident on the photoelectric conversion layer 4. In other words, the holes accumulated in the charge accumulation node 34 of each pixel 24 can be retained even after another incident of light on the photoelectric conversion layer 4, unless the holes in the charge accumulation node 34 are reset. Thus, even when sequential readout operations are performed row by row during the non-exposure period, holes are unlikely to be newly accumulated in the charge accumulation node 34 during the readout operations. Thus, a simple pixel circuit, such as the pixel 24 can provide a global shutter function without a transfer transistor and an additional accumulation capacitance. Thus, for example, this configuration is free from rolling distortion, which may occur in rolling shutters. Due to the simple pixel circuit, the pixels 24 used in the imaging device 100 can be advantageously downsized. Furthermore, in the imaging device 100, even if holes generated in the photoelectric conversion layer 4 during the exposure period remain in the non-exposure period, recombination of the remaining holes with electrons are promoted by the presence of the charge injection layer 5, and thus parasitic sensitivity can be reduced.

FIG. 10 is a timing chart indicating the voltage V2 supplied to the upper electrode 7 of the photoelectric converter 10A and an example of the timing of the operation in each row of the pixel array PA of the imaging device 100. For clarity, FIG. 10 shows only the change in the voltage V2 and the timing of exposure and signal readout for each of the rows indicated by R0 to R7 of the pixel array PA. In the imaging device 100, during the non-exposure period N, the voltage supply circuit 19 supplies a voltage Vb to the upper electrode 7 as the voltage V2 that allows the bias voltage Vo to fall within the first voltage range, and during the exposure period E, supplies a voltage Va as the voltage V2 that allows the bias voltage Vo to fall within the second voltage range.

As indicated in FIG. 10, during the non-exposure period N, signal readout R of the pixels 24 in the rows from R0 to R7 is sequentially performed. As described above, in the non-exposure period N, holes are unlikely to be newly accumulated in the charge accumulation node 34 during the readout operation because the bias voltage Vo is within the second voltage range, and furthermore, recombination of the remaining holes with electrons is promoted by the presence of the charge injection layer 5, reducing parasitic sensitivity. The timing of the beginning and end of the exposure period E is the same for the pixels 24 in all rows from R0 to R7. In other words, the imaging device 100 has a global shutter function in which rows of all the pixel array PA are collectively exposed while signals are sequentially read out of the pixels 24 in each row.

As described above, this embodiment can provide the imaging device 100 in which parasitic sensitivity can be reduced.

The operation of the imaging device 100 is not limited to the above example. For example, the operation may be performed to provide an electronic Neutral Density (ND) filter function to adjust the sensitivity of photoelectric conversion.

For example, in the exposure period E in FIG. 10, the voltage supply circuit 19 supplies, as the voltage V2, instead of the voltage Va, a voltage equivalent to the ND value, which is a fold reduction in sensitivity predetermined based on the relation between the bias voltage and the current value at that voltage (that is, the amount of holes generated in the photoelectric conversion layer 4 that are taken out), to the upper electrode 7, and thus the imaging device 100 can have an electronic ND filter function.

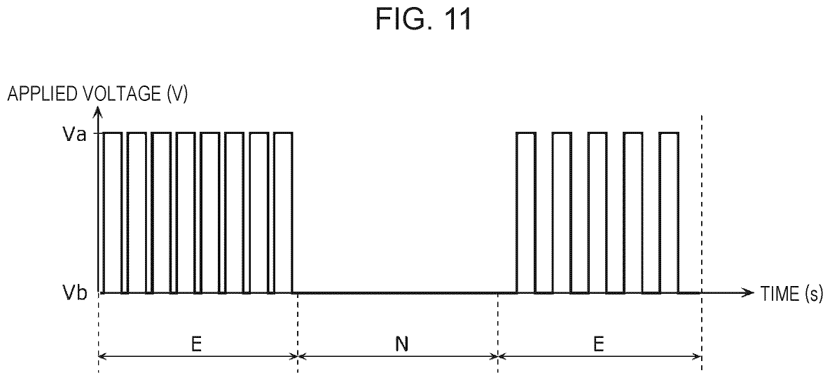

FIG. 11 is a timing chart indicating an example of the operation of adjusting the sensitivity of photoelectric conversion by using the pulse duty control method in the imaging device 100. As indicated in FIG. 11, the voltage supply circuit 19 supplies, for example, a pulsed voltage that repeats the above-described voltage Va and voltage Vb during the exposure period E. As above, the first period during which the voltage supply circuit 19 supplies the voltage Va, which is an example of the first voltage, and the second period during which the voltage supply circuit 19 supplies the voltage Vb, which is an example of the second voltage, may be included in the same frame of the exposure period E. In this case, the voltage supply circuit 19 supplies a voltage to the upper electrode 7 with a duty ratio of pulse voltage having repeating voltages Va and Vb being set at a duty ratio corresponding to the predetermined ND value. This also enables the imaging device 100 to have an electronic ND filter function. In this case, in the second period of the exposure period E during which the voltage Vb is applied to the upper electrode 7, the parasitic sensitivity is reduced as in the non-exposure period N above, enabling the set ND value to be readily and accurately achieved.

Thus, even when the imaging device 100 has an electronic ND filter function, the parasitic sensitivity of the imaging device 100 is reduced as described above, and thus the imaging device 100 can achieve low-noise imaging.

### EXAMPLE

Hereinafter, the photoelectric conversion element of the present disclosure will be described in detail, but the present disclosure should not be limited to the following example. Specifically, a photoelectric conversion element according to the embodiment of this disclosure and a photoelectric conversion element for property comparison were produced and evaluated for parasitic sensitivity.

### Production of Photoelectric Conversion Element

Photoelectric conversion elements according to Example and Comparative Example were produced.

### Example

A glass substrate having an ITO film was used as the support substrate. The ITO film was used as the lower electrode 2, and 9,9′-[1,1′-Biphenyl]-4,4′-diylbis[3,6-bis(1,1-dimethylethyl)]-9H-carbazole (tBu-CBP), which is a material of the electron blocking layer 3, was deposited on the lower electrode 2 by vacuum evaporation to form the electron blocking layer 3.

Next, as materials of the photoelectric conversion layer 4, subphthalocyanine, which is a donor organic semiconductor material, and C60 fullerene, which is an acceptor organic semiconductor material, were co-evaporated on the electron blocking layer 3 by vacuum evaporation such that the weight ratio becomes 1:3 to form the photoelectric conversion layer 4. The thickness of the photoelectric conversion layer 4 produced at this time was about 400 nm. As subphthalocyanine, boron subphthalocyanine chloride (SubPc), which has boron (B) as the central metal and a chloride ion coordinated to B as a ligand, was used.

Next, C60 fullerene as the material of the first layer 6A of the charge injection layer 5 was deposited on the photoelectric conversion layer 4 by vacuum evaporation with a metal shadow mask therebetween to form a film having a thickness of 10 nm. Furthermore, SubPc as the material of the second layer 6B of the charge injection layer 5 was deposited on the first layer 6A to form a film having a thickness of 10 nm.

Next, an ITO film having a thickness of 30 nm as the upper electrode 7 was formed on the second layer 6B of the charge injection layer 5 by sputtering, and then an Al₂O₃ film was formed on the upper electrode 7 as a sealing film by atomic layer deposition, and thus the photoelectric conversion element of Example was produced.

### Comparative Example

A photoelectric conversion element of Comparative Example was produced in the same way as in Example except that the first layer 6A was not formed.

### Measurement of Ionization Potential and Electron Affinity of Materials

The ionization potential and electron affinity were measured for materials used in Example and Comparative Example.

In the measurement of ionization potential, samples were first prepared by forming films of materials used in Example and Comparative Example on glass substrates each having an ITO film. Next, the number of photoelectrons in each of the prepared samples when the energy of UV irradiation was varied was measured using an atmospheric photoelectron spectrometer (AC-3, available from RIKEN KEIKI Co., Ltd.), and the energy position at the beginning of detection of the photoelectrons was defined as the ionization potential.

In the measurement of electron affinity, samples were prepared by forming films of materials used in Example and Comparative Example on quartz substrates. Next, the absorption spectra of the prepared samples were measured using a spectrophotometer (U4100, Hitachi High-Tech Corporation), and the optical band gap was calculated from the result at the absorption edge of the obtained absorption spectra. The electron affinity was estimated by subtracting the ionization potential obtained by the above ionization potential measurement from the calculated optical band gap.

Table 1 shows the ionization potential and electron affinity of the materials used in Example and Comparative Example.

TABLE 1

| | | | Ionization | Electron |
|---|---|---|---|---|
| | | | Potential | Affinity |
| Layer | | Material | (eV) | (eV) |
| Electron Blocking Layer | | tBu—CBP | 5.8 | 2.7 |
| Photoelectric | Donor Organic | SubPc | 5.5 | 3.4 |
| Conversion | Semiconductor | | | |
| Layer | Material | | | |
| | Acceptor Organic | C60 | 6.2 | 4.2 |
| | Semiconductor | fullerene | | |
| | Material | | | |
| Charge | First Layer | C60 | 6.2 | 4.2 |
| Injection | | fullerene | | |
| Layer | Second Layer | SubPc | 5.5 | 3.4 |

As indicated in Table 1, in the photoelectric conversion element of Example, the electron affinity of C60 fullerene forming the first layer 6A of the charge injection layer 5 is 4.2 eV, the ionization potential of the SubPc forming the second layer 6B of the charge injection layer 5 is 5.5 eV, and the difference between them is 1.3 eV.

In contrast, although the photoelectric conversion layer 4 contains SubPc and C60 fullerene like the charge injection layer 5, materials of a mixed film having a bulk heterostructure are less affected by stabilization than a material of a single-material film. Thus, the difference between the ionization potential and the electron affinity of the materials of the mixed film is larger than that of the single-material films. Thus, the difference between the electron affinity of C60 fullerene, which is the acceptor organic semiconductor material, and the ionization potential of SubPc, which is the donor organic semiconductor material, is larger in the photoelectric conversion layer 4 than in the charge injection layer 5. Specifically, the difference between the electron affinity of C60 fullerene, which is the acceptor organic semiconductor material, and the ionization potential of SubPc, which is the donor organic semiconductor material, in the photoelectric conversion layer 4 is larger than 1.3 eV.

Thus, the difference between the electron affinity of the first layer 6A and the ionization potential of the second layer 6B in the photoelectric conversion element of Example is smaller than the difference between the electron affinity of the acceptor organic semiconductor material and the ionization potential of the donor organic semiconductor material in the photoelectric conversion layer 4.

The ionization potential of the C60 fullerene forming the first layer 6A is larger than that of the SubPc forming the second layer 6B. The electron affinity of the C60 fullerene forming the first layer 6A is larger than that of the SubPc forming the second layer 6B.

In the photoelectric conversion element of Example, the materials of the first and second layers 6A and 6B of the charge injection layer 5 and the donor and acceptor organic semiconductor materials of the photoelectric conversion layer 4 were the same, but they may be different as long as the above energy magnitude relation can be obtained.

### Evaluation of Parasitic Sensitivity

To evaluate the parasitic sensitivity of the photoelectric conversion elements of Example and Comparative Examples, the current density was measured in a light condition (under irradiation of 1000 1×) and a dark condition. The current density was measured by using a semiconductor device parameter analyzer (B1500A, Keysight Technologies, Inc.). Specifically, the bias voltage applied between two electrodes of the photoelectric conversion element, i.e., between the upper electrode 7 and the lower electrode 2 was varied, and the current-voltage characteristics in light and dark conditions were measured.

Of the reverse biasing and forward biasing of the bias voltage, the forward biasing is applying a negative voltage to the lower electrode 2 or applying a positive voltage to the upper electrode 7, and the forward biasing is applying a positive voltage to the lower electrode 2 or applying a negative voltage to the upper electrode 7.

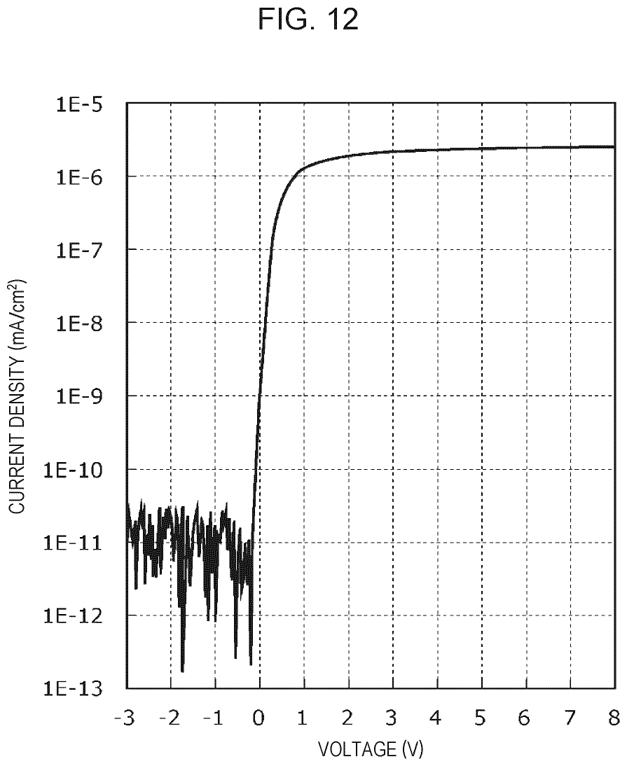

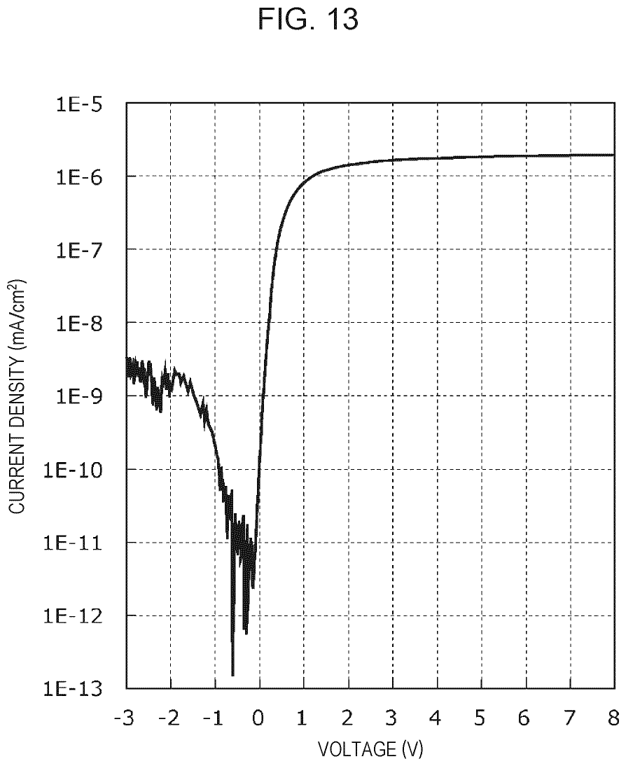

FIG. 12 indicates the current density-voltage characteristics when a bias voltage was applied to the photoelectric conversion element of Example. In contrast, FIG. 13 indicates the current density-voltage characteristics when a bias voltage was applied to the photoelectric conversion element of Comparative Example. In FIGS. 12 and 13, the vertical axis is logarithmic and indicates the difference between the current density in the light condition and the current density in the dark condition. In FIGS. 12 and 13, the horizontal axis represents voltages at the normal axis. Of the voltages represented by the horizontal axis, the reverse bias voltage corresponds to a positive voltage, and the forward bias voltage corresponds to a negative voltage.

As indicated in FIG. 13, in the photoelectric conversion element of Comparative Example, the current density in the dark condition and the current density in the light condition are different except for at a very small bias voltage close to 0 V. Thus, it can be said that the parasitic sensitivity is large no matter what voltage is set during the non-exposure period, and there is almost no voltage applicable during the non-exposure period.

In contrast, as indicated in FIG. 12, in the photoelectric conversion element of Example, the current density in the light condition and the current density in the dark condition show little difference over a wide range of bias voltages below 0 V. By setting the voltage during the non-exposure period so that the bias voltage falls within this voltage range, the parasitic sensitivity can be reduced.

As described above, in the photoelectric conversion element according to the present disclosure, such as the photoelectric conversion element of Example, the ionization potential of the first layer 6A is larger than that of the second layer 6B, the electron affinity of the first layer 6A is larger than that of the second layer 6B, and the difference between the electron affinity of the first layer 6A and the ionization potential of the second layer 6B is smaller than the difference between the electron affinity of the acceptor organic semiconductor material and the ionization potential of the donor organic semiconductor material. It was confirmed that this configuration can make a difference between the current density in the light condition and the current density in the dark condition small and thus the effect of reducing parasitic sensitivity can be obtained.

The photoelectric conversion element and the imaging device according to the present disclosure have been described using the embodiment and Example, but the present disclosure should not be limited to the embodiment and Example. Without departing from the gist of the present disclosure, various changes may be added to the embodiment and Example by a person skilled in the art, and another embodiment achieved by combining one or more of the components of the embodiment and Example is construed as being within the scope of the present disclosure.

The photoelectric conversion element according to the present disclosure is applicable to an imaging device, an optical sensor, and a photodetector. The imaging device according to the present disclosure is applicable to various camera systems and sensor systems, such as a medical camera, a surveillance camera, an in-vehicle camera, a ranging camera, a microscope camera, a drone camera, and a robot camera.

What is claimed is:

1. A photoelectric conversion element comprising:
a photoelectric conversion layer that contains a donor semiconductor material and an acceptor semiconductor material and that converts light into a signal charge;
a first electrode that collects the signal charge;
a second electrode opposed to the first electrode with the photoelectric conversion layer disposed between the first electrode and the second electrode; and
a charge injection layer located between the second electrode and the photoelectric conversion layer, wherein
the charge injection layer includes a first layer and a second layer located on the first layer,
the first layer has an ionization potential that is larger than an ionization potential of the second layer,
the first layer has an electron affinity that is larger than an electron affinity of the second layer,
a difference between the electron affinity of the first layer and the ionization potential of the second layer is smaller than a difference between the electron affinity of the acceptor semiconductor material and the ionization potential of the donor semiconductor material.

2. The photoelectric conversion element according to claim 1, wherein the signal charge is a hole.

3. The photoelectric conversion element according to claim 2, wherein the first layer is located between the second layer and the photoelectric conversion layer.

4. The photoelectric conversion element according to claim 2, further comprising an electron blocking layer located between the first electrode and the photoelectric conversion layer.

5. The photoelectric conversion element according to claim 1, wherein the signal charge is an electron.

6. The photoelectric conversion element according to claim 5, wherein the second layer is located between the first layer and the photoelectric conversion layer.

7. The photoelectric conversion element according to claim 5, further comprising a hole blocking layer located between the first electrode and the photoelectric conversion layer.

8. The photoelectric conversion element according to claim 1, wherein the first layer contains a material identical to the acceptor semiconductor material.

9. The photoelectric conversion element according to claim 1, wherein the second layer contains a material identical to the donor semiconductor material.

10. The photoelectric conversion element according to claim 9, wherein
the photoelectric conversion layer is a mixed film containing the donor semiconductor material and the acceptor semiconductor material, and
the first layer contains a material identical to the acceptor semiconductor material.

11. An imaging device comprising:
the photoelectric conversion element according to claim 1; and
a charge accumulation region that is electrically connected to the first electrode and that accumulates the signal charge.

12. The imaging device according to claim 11, further comprising:
a voltage supply circuit that is electrically connected to the second electrode and that provides a potential difference between the first electrode and the second electrode, wherein
the voltage supply circuit supplies a first voltage to the second electrode in a first period and supplies a second voltage that is different from the first voltage in a second period that is different from the first period.
